(19) United States
(12) Patent Application Publication
(10) Pub. No.: US 2026/0297749 A1
(43) Pub. Date: Oct. 1, 2026

(54) PROCESSING APPARATUS FOR SUBSTRATE

(71) Applicant: NEXUSBE CO., LTD, Jeonju-si (KR)

(72) Inventors: Ki Taek JUNG, Namyangju-si (KR); Keun Sik KIM, Yongin-si (KR)

(73) Assignee: NEXUSBE CO., LTD, Jeonju-si (KR)

(21) Appl. No.: 19/540,701

(22) Filed: Feb. 15, 2026

(30) Foreign Application Priority Data
Mar. 28, 2025 (KR) 10-2025-0040191
Jun. 27, 2025 (KR) 10-2025-0085623

(51) Int. Cl. C23C 16/455; H10P 72/00

(52) U.S. Cl. CPC C23C 16/45565; C23C 16/45544; C23C 16/45546; H10P 72/0458

(57) ABSTRACT

The present disclosure relates to a substrate processing apparatus, and more particularly, to a substrate processing apparatus for processing a substrate in a state in which the substrate is disposed in a reaction chamber.

According to one aspect of an example embodiment of the present disclosure, a substrate processing apparatus includes a chamber assembly in which two sub-chamber units are disposed, a showerhead unit disposed in each of the two sub-chamber units and having a plurality of gas through-holes formed therein, a susceptor disposed in each of the two sub-chamber units, on an upper surface of which a substrate is seated, and a blocking portion configured to partition the chamber assembly to form at least two buffer regions that stabilize an internal pressure of the chamber assembly, the at least two buffer regions being regions between the two sub-chamber units and a region having one of the two sub-chamber units interposed therebetween, in which pressure is controlled between the at least two buffer regions and internal regions of the two sub-chamber units in accordance with an elevating position of the susceptor.

### TECHNICAL FIELD

The present disclosure relates to a substrate processing apparatus, and more particularly, to a substrate processing apparatus capable of performing deposition processes on two or more substrates simultaneously or individually in a single reaction chamber, and, even when an error occurs in a substrate deposition process in one chamber, preventing the substrate deposition process in the other chamber from being interrupted, thereby increasing mass-production yield.

### BACKGROUND ART

In general, to manufacture semiconductor devices, a silicon wafer undergoes a thin-film deposition process for depositing a source material, a photolithography process for exposing or shielding selected regions of such thin films by using a photosensitive material, an etching process for removing the thin film in selected regions to pattern the thin film as desired, and the like. Each of these processes is performed inside a reaction chamber designed to provide an optimal environment for the corresponding process.

A display manufacturing process may be considered as a process similar to the semiconductor device manufacturing process. Both require process execution in a chamber environment in which pressure can be stably controlled, and stable process control has a very large effect on the quality and yield of the final product.

For example, in low-pressure chemical vapor deposition (CVD) and atomic layer deposition (ALD) for depositing a predetermined film on a semiconductor substrate, various reaction gases (source gases) are used depending on the film to be deposited. In this case, the process is generally performed under a predetermined vacuum state to prevent the semiconductor substrate from reacting with air, and an increased pressure in the reaction chamber, which occurs when reaction gases are introduced into the reaction chamber, is finely adjusted through a pump system and maintained at a set process condition.

However, when an apparatus is configured such that deposition is performed on two or more substrates in a single reaction chamber, if an error occurs in a deposition process for one substrate, it becomes necessary to stop the deposition process for the other substrate, resulting in a significant decrease in mass-production yield. Such a problem may occur not only in processes for small semiconductor products but also in deposition processes for large display products.

### SUMMARY

### Technical Problem

The present disclosure has been devised to solve the above-described technical problems, and an object of the present disclosure is to provide a substrate processing apparatus capable of simultaneously processing two or more substrates in a single reaction chamber.

Another object of the present disclosure is to provide a substrate processing apparatus for improving mass-production yield and process efficiency.

The technical objects of the present disclosure are not limited to the above-mentioned technical objects, and other technical objects that are not mentioned will be clearly understood by those skilled in the art from the following description.

### Technical Solution

A substrate processing apparatus according to an example embodiment of the present disclosure includes a chamber assembly in which two sub-chamber units are disposed, a showerhead unit disposed in each of the two sub-chamber units and having a plurality of gas through-holes formed therein, a susceptor disposed in each of the two sub-chamber units, on an upper surface of which a substrate is seated, and a blocking portion configured to partitioning the chamber assembly to form at least two buffer regions that stabilize an internal pressure of the chamber assembly, the at least two buffer regions being regions between the two sub-chamber units and a region having one of the two sub-chamber units interposed therebetween, in which pressure is controlled between the at least two buffer regions and internal regions of the two sub-chamber units in accordance with an elevating position of the susceptor.

Here, the two sub-chamber units may include a first sub-chamber unit and a second sub-chamber unit, the blocking portion may include a first blocking member disposed to surround the first sub-chamber unit and a second blocking member disposed to surround the second sub-chamber unit, and a first buffer region among the at least two buffer regions may be formed between the first blocking member and the second blocking member.

In addition, a first communication hole communicating with the first buffer region may be formed in each of the first blocking member and the second blocking member.

In addition, the first communication hole may be formed at a position that is covered so as to be overlapped in a horizontal direction by elevation of the susceptor disposed in the first sub-chamber unit and the second sub-chamber unit.

In addition, a second buffer region among the at least two buffer regions may be formed between an inner wall of the chamber assembly and the first blocking member and between the inner wall of the chamber assembly and the second blocking member.

In addition, a second communication hole communicating with the second buffer region may be formed in each of the first blocking member and the second blocking member.

In addition, the second communication hole may be formed at a position that is covered so as to be overlapped in a horizontal direction by elevation of the susceptor disposed in the first sub-chamber unit and the second sub-chamber unit.

In addition, the first communication hole and the second communication hole may be formed at the same height in each of the first blocking member and the second blocking member.

In addition, the substrate processing apparatus may further include a gas supply assembly supplying a source gas, a reaction gas, and a purge gas to the showerhead unit, and a pumping assembly connected to an internal space of the chamber assembly.

In addition, the showerhead unit may be disposed at an upper side of the internal space of the first sub-chamber unit and the second sub-chamber unit, the susceptor may be disposed at a lower side of the internal space of the first sub-chamber unit and the second sub-chamber unit, the gas supply assembly may be connected to the showerhead unit from an upper side of the chamber assembly, and the pumping assembly may be connected to the second buffer region from a lower side of the chamber assembly.

### Advantageous Effects of Invention

According to the substrate processing apparatus and the processing method thereof according to an example embodiment of the present disclosure, various effects may be achieved as follows.

First, stable pressure control is possible when processing two or more substrates in a single reaction chamber.

Second, when a deposition error occurs for one substrate in a single reaction chamber, the deposition process is performed under stable pressure control without interrupting the deposition process for another substrate, thereby improving product quality and mass-production yield.

### BRIEF DESCRIPTION OF THE DRAWINGS

FIGS. 1 and 2 are schematic views illustrating a substrate processing apparatus according to an example embodiment of the present disclosure.

FIG. 3 is a circuit diagram of a gas supply assembly among the configurations of FIGS. 1 and 2.

FIG. 4 is a cross-sectional view illustrating a chamber assembly among the configurations of FIG. 1.

FIG. 5 is a perspective view illustrating a showerhead among the configurations of FIG. 1.

FIGS. 6A and 6B are views illustrating a partial cross-section of the showerhead among the configurations of FIG. 1.

FIG. 7 is a schematic configuration view for explaining a processing method of the substrate processing apparatus according to an example embodiment of the present disclosure.

FIGS. 8 and 9 are process execution tables illustrating a substrate processing method using the substrate processing apparatus according to an example embodiment of the present disclosure.

### BRIEF DESCRIPTION OF THE INVENTION

The advantages and features of the present disclosure and the accomplishing methods thereof will become apparent from the embodiments described below in detail with reference to the accompanying drawings. The present disclosure may, however, be embodied in many different forms and should not be construed as being limited to the embodiments set forth herein; rather, these embodiments are provided such that this disclosure will be thorough and complete, and will fully convey the scope of the present disclosure to those skilled in the art.

Although the terms “first” and “second” are used to describe various components, the components are not limited by the terms. These terms are provided simply to distinguish one component from another. Accordingly, the first component mentioned herein may also be the second component within the technical spirit of the present disclosure.

The same or similar reference symbols are used throughout the drawings to refer to the same or like parts.

The features of various aspects of the present disclosure can be partially or entirely adhered to or combined with each other and can be interlocked and operated in technically various ways as understood by those skilled in the art, and the aspects can be carried out independently of or in association with each other.

Meanwhile, potential effects that may be expected from technical features of the present disclosure that are not specifically mentioned in the specification of the present disclosure are regarded as described in the present specification, and the present embodiment is provided to more completely describe the present disclosure to those skilled in the art, such that the content illustrated in the drawings may be exaggerated compared to an actual implementation of the disclosure, and detailed descriptions of configurations that are deemed to unnecessarily obscure the gist of the present disclosure are omitted or briefly described.

Hereinafter, example embodiments of the present disclosure will be described in detail with reference to the accompanying drawings.

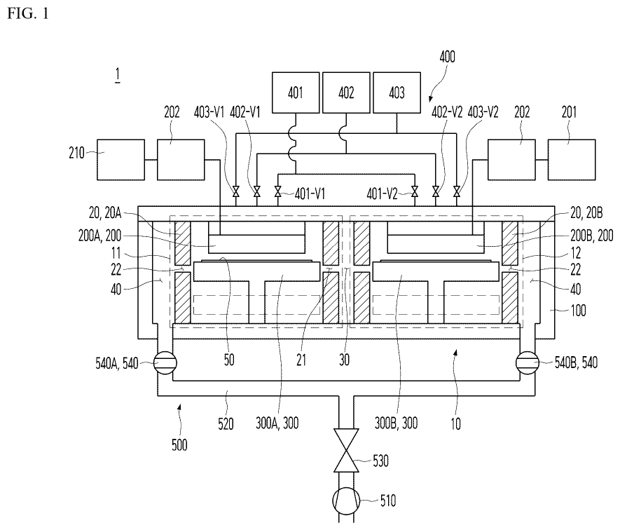

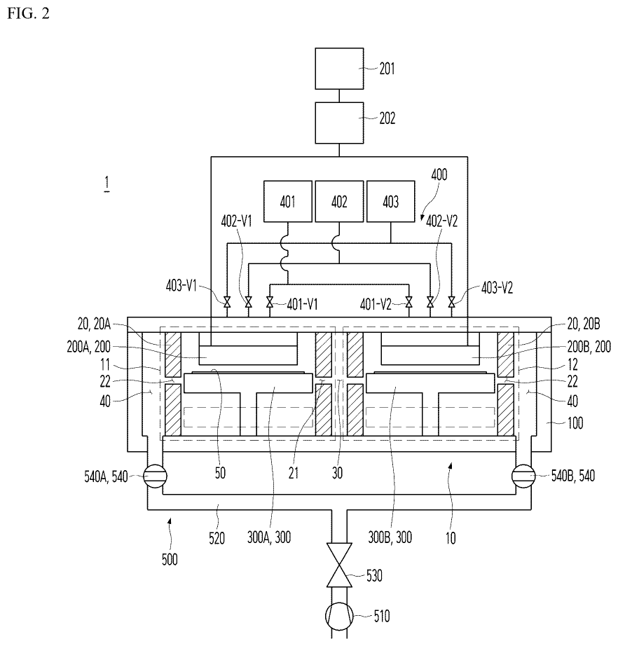

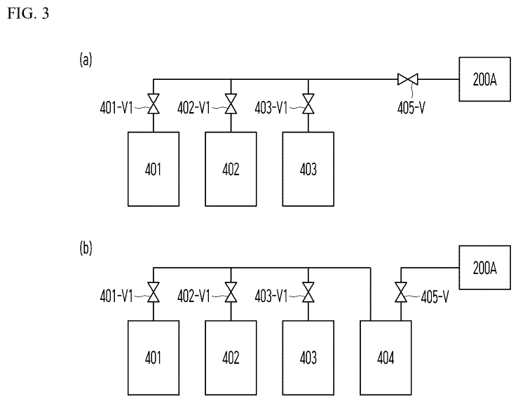

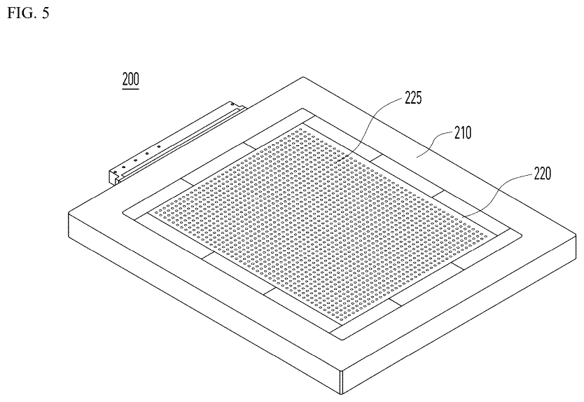

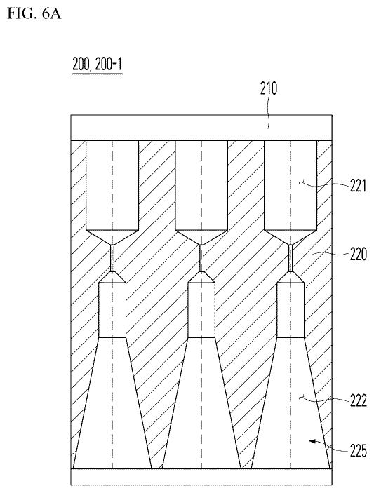

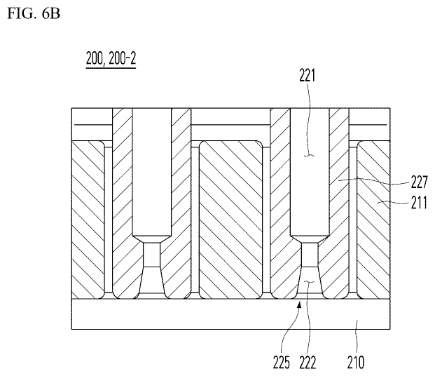

FIGS. 1 and 2 are schematic views illustrating a substrate processing apparatus according to an example embodiment of the present disclosure, FIG. 3 is a circuit diagram of a gas supply assembly among the configurations of FIGS. 1 and 2, FIG. 4 is a cross-sectional view illustrating a chamber assembly among the configurations of FIG. 1, FIG. 5 is a perspective view illustrating a showerhead among the configurations of FIG. 1, and FIGS. 6A and 6B are views illustrating a partial cross-section of the showerhead among the configurations of FIG. 1.

Referring to FIGS. 1 to 6B, a substrate processing apparatus 1 according to an example embodiment of the present disclosure includes a chamber assembly 100 in which at least two sub-chamber units 10 are disposed. The chamber assembly 100 is a type of reaction chamber, and, in this example embodiment, it is assumed that the sub-chamber units 10 are provided as two units. That is, the sub-chamber unit 10 may include a first sub-chamber unit 11 and a second sub-chamber unit 12. The chamber assembly 100 forms a predetermined internal space, and the first sub-chamber unit 11 and the second sub-chamber unit 12 may be partitioned within the internal space of the chamber assembly 100.

In addition, the substrate processing apparatus 1 according to an example embodiment of the present disclosure may further include a showerhead unit 200 and a susceptor 300. The showerhead unit 200 and the susceptor 300 may be disposed in each of the first sub-chamber unit 11 and the second sub-chamber unit 12. That is, the showerhead unit 200 may include a first showerhead unit 200A disposed in the first sub-chamber unit 11 and a second showerhead unit 200B disposed in the second sub-chamber unit 12, and the susceptor 300 may include a first susceptor 300A disposed in the first sub-chamber unit 11 and a second susceptor 300B disposed in the second sub-chamber unit 12.

Here, the substrate processing apparatus 1 according to an example embodiment of the present disclosure may further include a blocking portion 20 partitioning the two sub-chamber units 10, respectively. The blocking portion 20 may include a first blocking member 20A disposed to surround the first sub-chamber unit 11 among the two sub-chamber units 10 and a second blocking member 20B disposed to surround the second sub-chamber unit 12 among the two sub-chamber units 10. Lower ends of the first blocking member 20A and the second blocking member 20B may be fixed to a bottom surface of the internal space of the chamber assembly 100, and upper ends thereof may be fixed to a ceiling surface of the internal space of the chamber assembly 100.

The internal space of the chamber assembly 100 is partitioned into the first sub-chamber unit 11 and the second sub-chamber unit 12 by the blocking portion 20, and two substrates may be individually introduced into the first sub-chamber unit 11 and the second sub-chamber unit 12 so that substrate processing may be performed simultaneously or at different times in the two spaces. Here, the substrate processing may include typical semiconductor substrate processing and may include, for example, any one of a thin-film deposition process, a photolithography process, and an etching process.

The above-described showerhead unit 200 and the susceptor 300 may be disposed in each of the first sub-chamber unit 11 and the second sub-chamber unit 12. That is, the first showerhead unit 200A and the first susceptor 300A may be disposed in the first sub-chamber unit 11, and the second showerhead unit 200B and the second susceptor 300B may be disposed in the second sub-chamber unit 12.

The first showerhead unit 200A and the second showerhead unit 200B may be disposed at a relatively upper side in the first sub-chamber unit 11 and the second sub-chamber unit 12, respectively, and the first susceptor 300A and the second susceptor 300B may be disposed at a relatively lower side in the first sub-chamber unit 11 and the second sub-chamber unit 12, respectively.

Here, the first susceptor 300A and the second susceptor 300B may be provided in a table shape and may be configured to be elevatable in a vertical direction in the internal spaces of the first sub-chamber unit 11 and the second sub-chamber unit 12, respectively.

More specifically, the first susceptor 300A and the second susceptor 300B are provided at lower sides of the internal spaces of the first sub-chamber unit 11 and the second sub-chamber unit 12, respectively, which are relatively lower than the first showerhead unit 200A and the second showerhead unit 200B, and may be moved upward to be close to lower surfaces of the first showerhead unit 200A and the second showerhead unit 200B during a thin-film deposition process in which reaction gases are supplied through the first showerhead unit 200A and the second showerhead unit 200B.

Meanwhile, referring to FIGS. 1 and 2, the substrate processing apparatus 1 according to an example embodiment of the present disclosure may further include a gas supply assembly 400 supplying a source gas 401, a reaction gas 402, and a purge gas 403 to the showerhead unit 200.

The gas supply assembly 400 may individually supply gases suitable for a corresponding process of the substrate 50 through supply pipes branched from the source gas 401, the reaction gas 402, and the purge gas 403 toward the first showerhead unit 200A and the second showerhead unit 200B, respectively. For this purpose, each supply pipe may be provided with a first control valve (401-V1, 401-V2), a second control valve (402-V1, 402-V2), and a third control valve (403-V1, 403-V2). In addition, an RF generator 201 and an RF matcher 202, which are power supply modules for plasma generation, may be connected to the showerhead unit 200.

Referring to FIG. 3(a), the supply amounts of the source gas 401, the reaction gas 402, and the purge gas 403 are individually controlled by the first control valve 401-V1, the second control valve 402-V1, and the third control valve 403-V1, respectively, and then a final supply amount to the showerhead unit 200A may be controlled by an integrated control valve 405-V.

Also, referring to FIG. 3(b), the supply amounts of the source gas 401, the reaction gas 402, and the purge gas 403 are individually controlled by the first control valve 401-V1, the second control valve 402-V1, and the third control valve 403-V1, respectively, and then integratedly supplied to a mixed zone (reference numeral not shown). A final supply amount of a mixed gas 404 mixed in the mixed zone to the showerhead unit 200A may be controlled by the integrated control valve 405-V.

Meanwhile, referring to FIG. 5, the showerhead unit 200 may include a mounting panel portion 210 fixed to internal spaces of the first sub-chamber unit 11 and the second sub-chamber unit 12, and a gas penetration portion 220 provided at a central region of the mounting panel portion 210 and having a plurality of gas through-holes 225 formed to penetrate in a thickness direction.

As referenced in FIGS. 6A and 6B, the plurality of gas through-holes 225 formed in the mounting panel portion 210 may have a gas inlet hole 221 and a gas outlet hole 222, and a lower end portion of the gas outlet hole 222 may be formed in a shape in which a horizontal area of the hole gradually increases.

In addition, as for the showerhead unit 200, as referenced in FIG. 6(a), the plurality of gas through-holes 225 provided with the gas inlet hole 221 and the gas outlet hole 222 may be integrally formed in the gas penetration portion 220.

However, the plurality of gas through-holes 225 do not necessarily need to be integrally formed in the gas penetration portion 220. As referenced in FIG. 6(b), a plurality of gas-through pins 227 having the gas inlet hole 221 and the gas outlet hole 222 may be integrally formed in the gas penetration portion 220, and the gas penetration portion 220 may be detachably coupled to the mounting panel 210 such that the plurality of gas-through pins 227 pass through a plurality of mounting holes 211 formed in the mounting panel portion 210. As such, if the gas penetration portion 220 is detachably coupled to the mounting panel 210, when a specification of the gas inlet hole 221 and the gas outlet hole 222 is changed, only the gas penetration portion 220 may be separated from the mounting panel 210 and easily replaced.

Such a gas supply assembly 400 is preferably disposed at an outer upper side of the chamber assembly 100 and connected to the showerhead unit 200, because the showerhead unit 200 to which the gas supply assembly 400 is connected is located at a relatively upper side in each internal space of the first sub-chamber unit 11 and the second sub-chamber unit 12 of the chamber assembly 100.

Meanwhile, referring to FIGS. 1 and 2, the substrate processing apparatus 1 according to an example embodiment of the present disclosure may further include a pumping assembly 500 connected to the internal space of the chamber assembly 100.

When gases are introduced into the internal space of the chamber assembly 100 using the gas supply assembly 400, the pressure temporarily increases, and the pumping assembly 500 performs a role of maintaining the increased pressure at a preset process condition. In addition, the pumping assembly 500 may continuously discharge unreacted gases and reaction by-products generated during the thin-film deposition process performed using the gas supply assembly 400.

The pumping assembly 500 as such may include a vacuum pump 510, an exhaust line 520 connecting the vacuum pump 510 to the internal space of the chamber assembly 100, a valve 530 installed on the exhaust line 520, and a pressure measuring unit 540. When the exhaust line 520 branches and is connected to each of the first sub-chamber unit 11 and the second sub-chamber unit 12 as shown in FIGS. 1 and 2, a first pressure measuring unit 540A and a second pressure measuring unit 540B may be separately installed as the pressure measuring unit 540 on each branch exhaust line 520.

Meanwhile, referring to FIGS. 1 and 2, two or more buffer regions 30 and 40 may be formed in the internal space of the chamber assembly 100 by the blocking portion 20. Here, the two or more buffer regions 30 and 40 may include a first buffer region 30 formed between the two sub-chamber units (i.e., the first sub-chamber unit 11 and the second sub-chamber unit 12), and a second buffer region 40 formed between one of the two sub-chamber units 11 and 12 (e.g., the first sub-chamber unit 11) and an inner wall of the chamber assembly 100 or between the other of the two sub-chamber units 11 and 12 (e.g., the second sub-chamber unit 12) and the inner wall of the chamber assembly 100.

The first buffer region 30 may be defined as being formed in one location in a space between the first sub-chamber unit 11 and the second sub-chamber unit 12, and the second buffer region 40 may be defined as being formed in two locations in spaces between each blocking portion 20 of the first sub-chamber unit 11 and the second sub-chamber unit 12, which are spaced apart about the first buffer region 30, and the inner wall of the chamber assembly 100. That is, the first buffer region 30 may be formed between the first blocking member 20A and the second blocking member 20B, and the second buffer region 40 may be formed between the inner wall of the chamber assembly 100 and the first blocking member 20A and between the inner wall of the chamber assembly 100 and the second blocking member 20B.

Here, a first communication hole 21 communicating with the first buffer region 30 may be formed in each of the first blocking member 20A and the second blocking member 20B. The first sub-chamber unit 11 and the second sub-chamber unit 12 each communicate with the first buffer region 30 through the first communication hole 21, and the first buffer region 30 may perform a role of stabilizing an internal pressure during a substrate processing process in the internal spaces of the first sub-chamber unit 11 and the second sub-chamber unit 12 through the first communication hole 21.

The first communication hole 21 may be formed at a position that is covered so as to be overlapped in a horizontal direction by elevation of the susceptor 300 disposed in the first sub-chamber unit 11 and the second sub-chamber unit 12.

More specifically, when the susceptor 300 has a predetermined thickness in an up-down direction, the first communication hole 21 may be covered in a horizontal direction through a thickness portion of the susceptor 300 depending on the elevating position of the susceptor 300. In this case, the first communication hole 21 is not completely closed by the susceptor 300, but this means that a communication area with the first buffer region 30 may decrease or increase depending on the elevating position of the susceptor 300.

In addition, a second communication hole 22 communicating with the second buffer region 40 may be formed in each of the first blocking member 20A and the second blocking member 20B. The first sub-chamber unit 11 and the second sub-chamber unit 12 each communicate with the second buffer region 40 through the second communication hole 22, and the second buffer region 40 may perform a role of stabilizing an internal pressure during a substrate processing process in the internal spaces of the first sub-chamber unit 11 and the second sub-chamber unit 12 through the second communication hole 22.

Here, the second communication hole 22 and the first communication hole 21 may be formed at portions of the first blocking member 20A and the second blocking member 20B corresponding to the same height. Thus, the second communication hole 22 may be understood as being formed, like the first communication hole 21, at a position that is covered so as to be overlapped in a horizontal direction by elevation of the susceptor 300 disposed in the first sub-chamber unit 11 and the second sub-chamber unit 12. In addition, a communication area with the second buffer region 40 may decrease or increase depending on the elevating position of the susceptor 300.

Meanwhile, as referenced in FIGS. 1 and 2, the pumping assembly 500 may be disposed at a lower portion of the chamber assembly 100. More specifically, the pumping assembly 500 may be installed such that an exhaust line 510 is connected to the second buffer region 40 among the internal space of the chamber assembly 100.

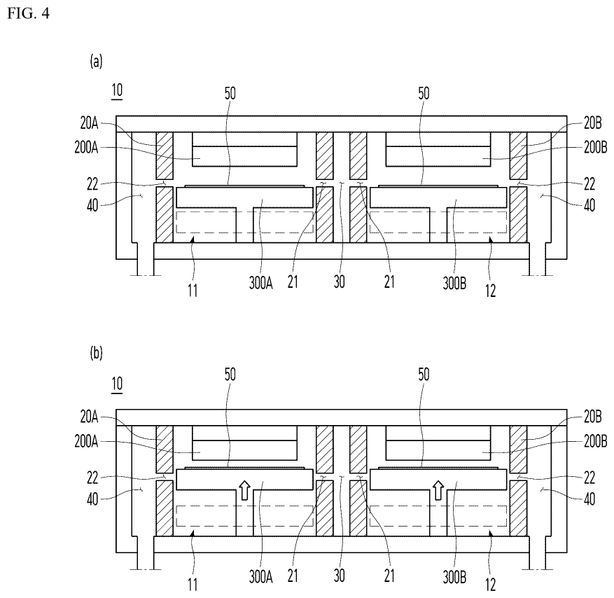

A substrate processing process for two substrates using the substrate processing apparatus 1 according to an example embodiment of the present disclosure configured as described above will be briefly described with reference to FIG. 4 as follows.

Referring to FIG. 4(a), the chamber assembly 100 having an internal space corresponding to a single reaction chamber has two process spaces partitioned into the first sub-chamber unit 11 and the second sub-chamber unit 12 by the blocking portion 20. The first susceptor 300A of the first sub-chamber unit 11 and the second susceptor 300B of the second sub-chamber unit 12 are positioned in a lowered state, and the substrates 50 to be processed are seated on upper portions of the first susceptor 300A and the second susceptor 300B, respectively.

Referring to FIG. 4(b), the first susceptor 300A and the second susceptor 300B on which the substrates 50 are seated move upward close to lower surfaces of the first showerhead unit 200A and the second showerhead unit 200B in the internal spaces of the first sub-chamber unit 11 and the second sub-chamber unit 12 to perform a thin-film deposition process by sequential supply of various gases through the gas supply assembly 400.

In this case, a stop position after elevation of the first susceptor 300A and the second susceptor 300B is preferably set to correspond to positions of the first communication hole 21 and the second communication hole 22 formed in the first sub-chamber unit 11 and the second sub-chamber unit 12.

A volume of a space between the first showerhead unit 200A and the first susceptor 300A at the stop position after elevation or between the second showerhead unit 200B and the second susceptor 300B at the stop position after elevation corresponds to a deposition process volume for the thin-film deposition process, and the thin-film deposition process among the substrate processing process may be performed in the deposition process volume, which is formed smaller than other volumes excluding the deposition process volume in the total volume of the first sub-chamber unit 11 and the second sub-chamber unit 12.

In addition, during the thin-film deposition process, the first susceptor 300A and the second susceptor 300B are elevated to heights corresponding to the first communication hole 21 and the second communication hole 22 formed in the first sub-chamber unit 11 and the second sub-chamber unit 12, and cover the first communication hole 21 and the second communication hole 22 in a horizontal direction, respectively, so that the process may be performed under a stable process pressure environment through the first buffer region 30 and the second buffer region 40.

For example, even if a temporary pressure increase occurs in the internal spaces of the first sub-chamber unit 11 and the second sub-chamber unit 12 due to introduction of gases using the gas supply assembly 400, a stabilized pressure environment may be maintained through the first buffer region 30 communicating through the first communication hole 21. In addition, among the introduced gases, unreacted gases and reaction by-products may minimize an influence of exhaust pressure on the internal spaces of the first sub-chamber unit 11 and the second sub-chamber unit 12 through the second buffer region 40 connected to the pumping assembly 500.

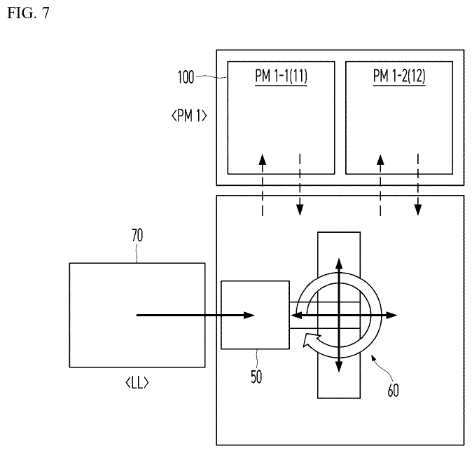

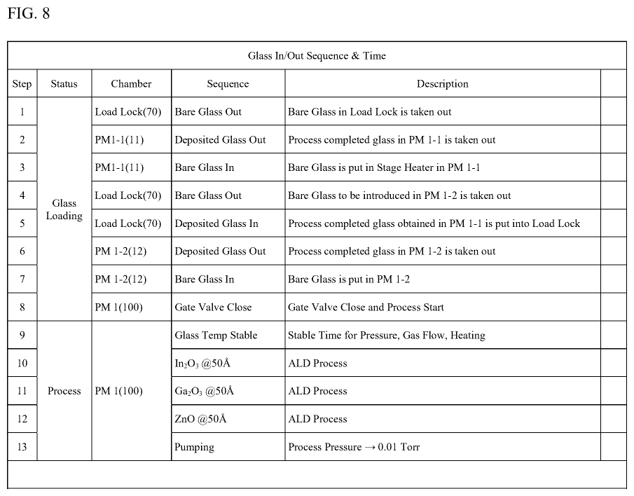

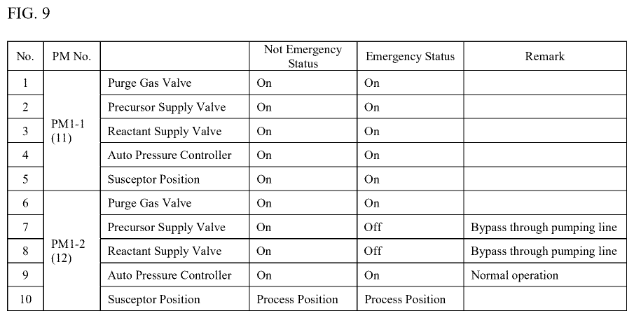

FIG. 7 is a schematic configuration view for explaining a processing method of the substrate processing apparatus according to an example embodiment of the present disclosure, and FIGS. 8 and 9 are process execution tables illustrating a substrate processing method using the substrate processing apparatus according to an example embodiment of the present disclosure.

Referring to FIGS. 7 to 9, in the substrate processing apparatus 1 according to an example embodiment of the present disclosure, since the first buffer region 30 and the second buffer region 40 are respectively configured to communicate with the first sub-chamber unit 11 and the second sub-chamber unit 12 through the first communication hole 21 and the second communication hole 22, individual control of deposition processes is possible when an error occurs in a deposition process in one of the chamber units 11 or 12.

Referring to FIG. 7, a transfer module 60 that transfers and supplies substrates 50 is disposed at a center, a load lock 70 (LL) for storing a substrate 50 to be processed or a processed substrate 50 is provided on one side of the transfer module 60, and a chamber assembly 100 among the configurations of the substrate processing apparatus 1 according to an example embodiment of the present disclosure is disposed on the other side of the transfer module 60.

As referenced in FIG. 7, the chamber assembly 100 is a single reaction chamber in which the first sub-chamber unit 11 and the second sub-chamber unit 12 are disposed, and two substrates 50 may be processed simultaneously or at different times under the same vacuum environment conditions in the first sub-chamber unit 11 and the second sub-chamber unit 12.

For example, referring to FIG. 8, the transfer module 60 takes out a substrate 50 to be processed (bare glass) from the load lock 70, takes out a processed substrate 50 (deposited glass) from the first sub-chamber unit 11, and then introduces the substrate 50 to be processed into the first sub-chamber unit 11. Then, the transfer module 60 again takes out a substrate 50 to be processed from the load lock 70, stores the processed substrate 50 taken out from the first sub-chamber unit 11 in the load lock 60, takes out a processed substrate 50 from the second sub-chamber unit 12, and then introduces the substrate 50 to be processed into the second sub-chamber unit 12.

When the processed substrates 50 are sequentially taken out from the first sub-chamber unit 11 and the second sub-chamber unit 12 using the transfer module 60, and substrates 50 to be processed are again introduced into the first sub-chamber unit 11 and the second sub-chamber unit 12, a gate valve of a chamber gate (not shown) provided in the chamber assembly 100 is closed, and a substrate processing process (e.g., a thin-film deposition process using the gas supply assembly 400) is performed.

As shown in steps 9 to 13 of FIG. 8, the thin-film deposition process may include stabilizing a pressure of the internal space of the chamber assembly 100 as a pre-process step, then sequentially introducing each type of gas using the gas supply assembly 400 to deposit a film layer having a desired thickness on the substrate 50, and discharging unreacted gases and reaction by-products using the pumping assembly 500. In this example embodiment, a case where the thin-film deposition process is performed in an atomic layer deposition (ALD) manner is described as an example, but the present disclosure is not limited thereto.

Preferably, the thin-film deposition process as such is performed simultaneously in the first sub-chamber unit 11 and the second sub-chamber unit 12 so that substrate processing is completed simultaneously for the substrates 50. However, during the thin-film deposition process, one of the first sub-chamber unit 11 and the second sub-chamber unit 12 may be normally processed, while an error may occur in the deposition process of the other.

In this case, as referenced in FIG. 9, the first sub-chamber unit 11 in which the thin-film deposition process is normally performed completes the process under a stabilized pressure environment through the first buffer region 30 and the second buffer region 40 without interrupting the process, and the second sub-chamber unit 11 in which an error occurs in the deposition process may discharge gases introduced through the gas supply assembly 400 by bypassing them through the pumping assembly 500.

As such, in the present example embodiment in which the first sub-chamber unit 11 and the second sub-chamber unit 12 are provided to simultaneously process two substrates 50 in the internal space of the chamber assembly 100 provided as a single reaction chamber, even if a deposition process error occurs in one of the sub-chamber units 11 or 12, the substrate processing process in the normal sub-chamber unit 11 or 12 may be completed without interruption, thereby preventing a decrease in mass-production yield of the substrates 50.

That is, according to an example embodiment of the present disclosure, since two or more sub-chamber units 11 and 12 are provided to perform a thin-film deposition process through the gas supply assembly 400 at the same time, an advantage is provided in that a high-quality thin film may be deposited at a faster speed.

Meanwhile, although the thin-film deposition process in the specific processing process of the substrate processing apparatus 1 according to an example embodiment of the present disclosure has been mainly described as an atomic layer deposition (ALD) process for forming an atomic layer on the substrate 50, a configuration for depositing a film other than an atomic layer may also be included in example embodiments of the present disclosure.

Although one example embodiment of the present disclosure has been described above, the present disclosure is not limited thereto, but, on the contrary, is intended to cover various modifications and equivalent arrangements included within the spirit and scope of the appended claims, the detailed description of the invention, and the accompanying drawings.

### DESCRIPTION OF REFERENCE NUMERALS

10: Sub-chamber unit
11: First sub-chamber unit
12: Second sub-chamber unit
100: Chamber assembly
200: Showerhead unit
201: RF generator
202: RF matcher
300: Susceptor
400: Gas supply assembly
500: Pumping assembly

1. A substrate processing apparatus comprising:
a chamber assembly in which two sub-chamber units are disposed;
a showerhead unit disposed in each of the two sub-chamber units and having a plurality of gas through-holes formed therein;
a susceptor disposed in each of the two sub-chamber units, on an upper surface of which a substrate is seated; and
a blocking portion configured to partition the chamber assembly to form at least two buffer regions that stabilize an internal pressure of the chamber assembly, the at least two buffer regions being regions between the two sub-chamber units and a region having one of the two sub-chamber units interposed therebetween,
wherein pressure is controlled between the at least two buffer regions and internal regions of the two sub-chamber units in accordance with an elevating position of the susceptor.

2. The substrate processing apparatus of claim 1,
wherein the two sub-chamber units comprise a first sub-chamber unit and a second sub-chamber unit,
wherein the blocking portion comprises a first blocking member disposed to surround the first sub-chamber unit and a second blocking member disposed to surround the second sub-chamber unit, and
wherein a first buffer region among the at least two buffer regions is formed between the first blocking member and the second blocking member.

3. The substrate processing apparatus of claim 2,
wherein a first communication hole communicating with the first buffer region is formed in each of the first blocking member and the second blocking member.

4. The substrate processing apparatus of claim 3,
wherein the first communication hole is formed at a position that is covered so as to be overlapped in a horizontal direction by elevation of the susceptor disposed in the first sub-chamber unit and the second sub-chamber unit.

5. The substrate processing apparatus of claim 2,
wherein a second buffer region among the at least two buffer regions is formed between an inner wall of the chamber assembly and the first blocking member and between the inner wall of the chamber assembly and the second blocking member.

6. The substrate processing apparatus of claim 5,
wherein a second communication hole communicating with the second buffer region is formed in each of the first blocking member and the second blocking member.

7. The substrate processing apparatus of claim 6,
wherein the second communication hole is formed at a position that is covered so as to be overlapped in a horizontal direction by elevation of the susceptor disposed in the first sub-chamber unit and the second sub-chamber unit.

8. The substrate processing apparatus of claim 4,
wherein the first communication hole and the second communication hole are each formed at the same height in each of the first blocking member and the second blocking member.

9. The substrate processing apparatus of claim 4, further comprising:
a gas supply assembly supplying a source gas, a reaction gas, and a purge gas to the showerhead unit; and
a pumping assembly connected to an internal space of the chamber assembly.

10. The substrate processing apparatus of claim 9,
wherein the showerhead unit is disposed at an upper side of the internal space of the first sub-chamber unit and the second sub-chamber unit,
wherein the susceptor is disposed at a lower side of the internal space of the first sub-chamber unit and the second sub-chamber unit,
wherein the gas supply assembly is connected to the showerhead unit from an upper side of the chamber assembly, and
wherein the pumping assembly is connected to the second buffer region from a lower side of the chamber assembly.
